(19) United States
(12) Patent Application Publication
(10) Pub. No.: US 2010/0164535 A1
(43) Pub. Date: Jul. 1, 2010

(54) SEMICONDUCTOR DEVICE AND SEMICONDUCTOR TESTING METHOD

(76) Inventors: Hiroshi Hoshika, Osaka (JP); Takeshi Kawano, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/160,590

(22) PCT Filed: Nov. 14, 2006
(86) PCT No.: PCT/JP2006/322633

§ 371 Date: Jul. 10, 2008

(30) Foreign Application Priority Data
Jan. 18, 2006 (JP) 2006-010462

(51) Int. Cl. G01R 31/36; G01R 31/26

(52) U.S. Cl. 324/771; 324/765

(57) ABSTRACT

Using a scan test system, a power supply wiring (401) for flip-flops (300) and a power supply wiring (403) for a combinational circuit (307) are separated from each other, and an output of each flip-flop (300) is separated to an output terminal (306) to a scan chain and an output terminal (305) to the combinational circuit (307), and further, a load/hold terminal (304) is newly added to the flip-flop (300) as an output terminal to the combinational circuit (307) to hold a signal value. Therefore, quiescent stability waiting and patterning of next test vectors can be simultaneously performed, thereby reducing the IDDQ test time, resulting in a semiconductor device and a semiconductor testing method which can speed up the IDDQ test for a system LSI.

### TECHNICAL FIELD

The present invention relates to a semiconductor device which performs a quiescent power supply current test for a system LSI, and a semiconductor testing method.

### BACKGROUND ART

A recent semiconductor integrated circuit has succeeded in reducing its area with progress in microfabrication technology. Under such circumstances, demands to the semiconductor integrated circuit are significantly increased, and thereby the number of transistors incorporated in the circuit is dramatically increased. Therefore, it is becoming very difficult to execute a test for the semiconductor integrated circuit.

There is a scanning test as a method for testing a semiconductor integrated circuit. In the scanning test, all flip-flops (FF) in a semiconductor integrated circuit are set in their shift register states, and test vectors as values for test are applied to the FFs in the shift register states from an external terminal to restore the FFs to their normal operation states only for a predetermined period of time, and the test vectors are applied to an internal combinational circuit. Thereafter, the values of output results after the inputting of the test vectors are supplied from the combinational circuit to the FFs. After the output result values are latched by the FFs, the FFs are again set to the shift register states, and the output result values from the combinational circuit are output to the outside, and the values are monitored to specify faulty parts. The shift registers are referred to as a scan chain, the state where the operation of moving the data by the scan chain is referred to as a shift mode, and the state where the shift register states are halted and the test vectors are applied to the combinational circuit to obtain the output results from the combinational circuit is referred to as a capture mode.

In this scanning test method, however, there are cases where the failures cannot be excited by the test vectors depending on the faulty parts. Further, it is very difficult to excite all the failures in the LSI.

So, significance of a quiescent power supply current (hereinafter referred to as “IDDQ”) test method has been increased in recent years. It has conventionally been known that, in a CMOS integrated circuit, its power supply current value in the quiescent mode is as very low as a leakage current value. Accordingly, if physical failures in manufacturing occur in the CMOS integrated circuit, a very large IDDQ might flow, and thereby the failures are very likely to be excited, resulting in an increase in the significance of the IDDQ test method.

A conventional semiconductor IC testing method will be described with reference to FIGS. 9, 10, and 11.

FIG. 9 is a block diagram illustrating a semiconductor device having a conventional scanning test system.

In FIG. 9, the semiconductor device includes first to sixth FFs 101a to 101f, a combinational circuit 102, an FF normal data input terminal (hereinafter referred to as a D terminal) 105, an FF scan chain data input terminal (hereinafter referred to as a DT terminal) 106, an FF data output terminal (hereinafter referred to as a Q terminal) 107, and an FF clock input terminal (hereinafter referred to as a CLK terminal) 108. A power supply current (IDD) 104 and a power supply voltage (VDD) 109 are supplied from a power supply 110 to the respective FFs 101a to 101f and the combinational circuit 102 which are connected by a power supply wiring 103.

FIG. 10 is a schematic flowchart for explaining the IDDQ test for the semiconductor device having the scan test system.

With reference to FIG. 10, initially, a test vector for the IDDQ test is input to the scan chain from the DT terminal 106 of the first FF 101a in step 201. The test vector inputted from the DT terminal 106 sets the first FF 101a in the shift register state and is outputted from the Q terminal 107, and then the test vector is input to the DT terminal 106 of the second FF 101b in the scan chain, and subsequently, it is input to the fourth to sixth FFs 101d to 101f. This step is referred to as “patterning”.

In step 202, supply of a clock to the CLK terminals 108 of the FFs 101 in the scan chain is halted. For this purpose, the clock is fixed to H input.

Next, in step 203, it is waited until the power supply current 104 in the combinational circuit 102 becomes constant (quiescent stability mode). This step is referred to as “quiescent stability waiting”. When the power supply current 104 of the combinational circuit 102 goes into the quiescent stability mode, the power supply current value 104 is measured in step 204. Then, the measured current value is compared with a reference current value, and the semiconductor device is judged as a non-defective product when the measured current value is smaller than the reference current value (“PASS” in step 205). When the semiconductor device is judged as a non-defective product (“PASS” in step 205), it is checked whether all the test vectors for the IDDQ test have been inputted or not (step 206). When all the test vectors for the IDDQ test have been inputted (“Yes” in step 206), the IDDQ test is ended (step 207). When some test vectors for the IDDQ test have not yet been inputted (“No” in step 206), the process returns to step 201 to continue the IDDQ test.

On the other hand, when the measured current value is larger than the reference current value (“FAIL” in step 205), the semiconductor device is judged as a defective product, and the IDDQ test is ended at this point in time (step 207).

FIG. 11 is a diagram illustrating the power supply current waveform in the conventional IDDQ test.

In FIG. 11, it is assumed that the data at the DT terminal 106 are latched at the rising edges of the clock from the CLK terminal 108. After the test vectors for the IDDQ test (Data1, Data3, Data5 in FIG. 11) are input to the DT terminal 106 and output to the Q terminal 107, the clock at the CLK terminal 108 is fixed at H to halt the supply of the clock (step 202). Then, the power supply current value 104 goes into the quiescent stability waiting state (step 203a, 203b), and the power supply current value 104 is measured (step 204a, 204b) after the current value 104 becomes quiescent and stable. After the measurement of the power supply current 104, the measured current value is compared with the reference current value to perform defective/non-defective judgment.

In the IDDQ test method, since, after the test vector is inputted, a large power supply current flows while the signal is propagating toward the transistors in the circuit, a quiescent stability waiting time is required until the power supply current value is converged to enable measurement of the IDDQ value after the circuit goes into the quiescent mode. For example, as shown in FIG. 11, after the patterning of data 1 (step 201a), the quiescent stability waiting (step 203a), and the measurement (step 204a) are ended, the patterning for next data 3 (step 201b), the quiescent stability waiting (step 203b), and the measurement (step 204b) are performed.

For the reasons mentioned above, it is required to speedily execute the IDDQ test. As a technique for speeding up the IDDQ test, there is reported a technique of connecting an analog switch which is turned on when a large power supply current flows and turned off when the large current is converged, in series to a DC power supply between a VDD and a GND of a test-target semiconductor IC, thereby suppressing a voltage drop of the VDD with supplying a large current from the DC power supply when the large current flows, resulting in speed-up of the IDDQ test (refer to Patent Document 1).

Patent Document 1: Japanese Published Patent Application 2002-189053

### DISCLOSURE OF THE INVENTION

### Problems to be Solved by the Invention

In the conventional semiconductor IC testing method, the quiescent stability waiting time is required until the power supply current value of the semiconductor IC is converged and goes into the quiescent mode after the test vectors for the IDDQ test are inputted, thereby undesirably increasing the test time required for the IDDQ test.

The present invention is made to solve the above-described problems and has for its object to provide a semiconductor device and a semiconductor testing method which can avoid an increase in the test time of the IDDQ test.

### Measures to Solve the Problems

In order to solve the above-described problems, according to Claim 1 of the present invention, there is provided a semiconductor device having plural flip-flops to which test vectors for a quiescent power supply current test are inputted during a scan test mode while ordinary data are inputted during an ordinary use mode, which semiconductor device comprises a combinational circuit to which the test vectors or the ordinary data are supplied from the plural flip-flops in a scan chain; a flip-flop power supply for supplying a power supply voltage to the flip-flops, which is connected to the flip-flops by a power supply voltage supply wiring; a combinational circuit power supply for supplying a power supply voltage to the combinational circuit, which is connected to the combinational circuit by a power supply voltage supply wiring; and each of the flip-flops including a load/hold terminal to which a load/hold signal is inputted, said load/hold signal controlling as to whether the test vectors supplied from the scan chain during the quiescent power supply current test mode should be held in the flip-flop as data to be outputted to the combinational circuit, or outputted to the combinational circuit, an ordinary data output terminal for outputting the ordinary data from the flip-flops to the combinational circuit, and a scan chain data output terminal for outputting the test vectors from an n-th stage flip-flop (n: integer) to an (n+1)th stage flip-flop in the scan chain.

According to Claim 2 of the present invention, in a semiconductor device having a plurality of semiconductor devices defined in Claim 1, a load/hold control circuit for controlling inputs of load/hold signals to the respective semiconductor devices on the basis of a load/hold control signal supplied from a control terminal is provided in the semiconductor device including the plural semiconductor devices.

According to Claim 3 of the present invention, there is provided a method for testing a semiconductor device having plural flip-flops and a combinational circuit which receives the outputs of the plural flip-flops, which method comprises the steps of holding values of test vectors for a quiescent power supply current test in the flip-flops until inputting of the test vectors to all the flip-flops in a scan chain is completed; rewriting the values of the test vectors in the flip-flops to values of next test vectors when inputting of the next test vectors to all the flip-flops is completed, and holding the values of the rewritten test vectors in the flip-flops after the values of the test vectors in the flip-flops have been rewritten; and measuring a quiescent power supply current value at an external power supply terminal for the combinational circuit, and comparing the measured current value with a reference current value, when the values of the test vectors in the flip-flops are rewritten to the values of the next test vectors, and the values of the test vectors that have been held in the flip-flops before being rewritten to the next test vectors are input to the combinational circuit, and thereby the quiescent power supply current of the combinational circuit goes into the quiescent mode.

According to Claim 4 of the present invention, there is provided a method for testing a semiconductor device having plural flip-flops and a combinational circuit which receives the outputs from the plural flip-flops, which method comprises the steps of holding values of test vectors for a quiescent power supply current test in the flip-flops until inputting of the test vectors to all the flip-flops in a scan chain is completed; rewriting the values of the test vectors in the flip-flops to values of next test vectors when inputting of the next test vectors to all the flip-flops is completed, and holding the values of the rewritten test vectors in the flip-flops after the values of the test vectors in the flip-flops have been rewritten; and measuring the power supply current values at two or more points at a timing after a predetermined period has passed from when the test vectors are input to the combinational circuit and a timing after a further predetermined period has passed from that timing to calculate an inclination between the two current values, and comparing this inclination with a reference inclination, until the values of the test vectors in the flip-flops are rewritten to the values of the next test vectors, and the values of the test vectors that have been held in the flip-flops before being rewritten to the next test vectors are input to the combinational circuit and thereby the quiescent power supply current of the combinational circuit goes into the quiescent mode.

According to Claim 5 of the present invention, the semiconductor testing method defined in Claim 3 or 4 further includes previously calculating the number of state transitions which occur when each test vector for the quiescent power supply current test is input to the combinational circuit, before inputting the test vectors for the quiescent power supply current test into the flip-flops, and inputting the test vectors in ascending order of the number of state transitions.

According to Claim 6 of the present invention, in the semiconductor testing method defined in Claim 3, the test for the semiconductor device is performed for each semiconductor device in a semiconductor integrated circuit.

According to Claim 7 of the present invention, in the semiconductor testing method defined in Claim 4, the test for the semiconductor device is performed for each semiconductor device in a semiconductor integrated circuit.

### EFFECTS OF THE INVENTION

In the present invention, it is possible to obtain an advantageous effect that the test time can be reduced in the IDDQ test for a semiconductor device.

That is, according to Claim 1 of the present invention, there is provided a semiconductor device having plural flip-flops to which test vectors for a quiescent power supply current test are inputted during a scan test mode while ordinary data are inputted during an ordinary use mode, which semiconductor device comprises a combinational circuit to which the test vectors or the ordinary data are supplied from the plural flip-flops in a scan chain; a flip-flop power supply for supplying a power supply voltage to the flip-flops, which is connected to the flip-flops by a power supply voltage supply wiring; a combinational circuit power supply for supplying a power supply voltage to the combinational circuit, which is connected to the combinational circuit by a power supply voltage supply wiring; and each of the flip-flops including a load/hold terminal to which a load/hold signal is inputted, said load/hold signal controlling as to whether the test vectors supplied from the scan chain during the quiescent power supply current test mode should be held in the flip-flop as data to be outputted to the combinational circuit, or outputted to the combinational circuit, an ordinary data output terminal for outputting the ordinary data from the flip-flops to the combinational circuit, and a scan chain data output terminal for outputting the test vectors from an n-th stage flip-flop (n: integer) to an (n+1)th stage flip-flop in the scan chain. Therefore, it is possible to, simultaneously with outputting of the IDDQ test vectors using the scan chain, hold the IDDQ test vectors in the flip-flops while keeping the test vectors being outputted to the combinational circuit, thereby reducing the test time of the IDDQ test. Further, since the power supply current values of the flip-flops and the power supply current value of the combinational circuit can be separately measured, the test can be performed with higher precision.

According to Claim 2 of the present invention, in a semiconductor device having a plurality of semiconductor devices defined in Claim 1, a load/hold control circuit for controlling inputs of load/hold signals to the respective semiconductor devices on the basis of a load/hold control signal supplied from a control terminal is provided in the semiconductor device including the plural semiconductor devices. Therefore, the IDDQ test can be performed for each semiconductor device in the semiconductor integrated circuit.

According to Claim 3 of the present invention, there is provided a method for testing a semiconductor device having plural flip-flops and a combinational circuit which receives the outputs of the plural flip-flops, which method comprises the steps of holding values of test vectors for a quiescent power supply current test in the flip-flops until inputting of the test vectors to all the flip-flops in a scan chain is completed; rewriting the values of the test vectors in the flip-flops to values of next test vectors when inputting of the next test vectors to all the flip-flops is completed, and holding the values of the rewritten test vectors in the flip-flops after the values of the test vectors in the flip-flops have been rewritten; and measuring a quiescent power supply current value at an external power supply terminal for the combinational circuit, and comparing the measured current value with a reference current value, when the values of the test vectors in the flip-flops are rewritten to the values of the next test vectors, and the values of the test vectors that have been held in the flip-flops before being rewritten to the next test vectors are input to the combinational circuit, and thereby the quiescent power supply current of the combinational circuit goes into the quiescent mode. Therefore, the quiescent stability waiting and the patterning of next test vectors can be simultaneously performed, thereby reducing the test time of the IDDQ test.

According to Claim 4 of the present invention, there is provided a method for testing a semiconductor device having plural flip-flops and a combinational circuit which receives the outputs from the plural flip-flops, which method comprises the steps of holding values of test vectors for a quiescent power supply current test in the flip-flops until inputting of the test vectors to all the flip-flops in a scan chain is completed; rewriting the values of the test vectors in the flip-flops to values of next test vectors when inputting of the next test vectors to all the flip-flops is completed, and holding the values of the rewritten test vectors in the flip-flops after the values of the test vectors in the flip-flops have been rewritten; and measuring the power supply current values at two or more points at a timing after a predetermined period has passed from when the test vectors are input to the combinational circuit and a timing after a further predetermined period has passed from that timing to calculate an inclination between the two current values, and comparing this inclination with a reference inclination, until the values of the test vectors in the flip-flops are rewritten to the values of the next test vectors, and the values of the test vectors that have been held in the flip-flops before being rewritten to the next test vectors are input to the combinational circuit and thereby the quiescent power supply current of the combinational circuit goes into the quiescent mode. Therefore, defective/non-defective judgment can be performed before measuring the IDDQ values after the quiescent stability waiting, thereby reducing the test time of the IDDQ test.

According to Claim 5 of the present invention, the semiconductor testing method defined in Claim 3 or 4 further includes previously calculating the number of state transitions which occur when each test vector for the quiescent power supply current test is input to the combinational circuit, before inputting the test vectors for the quiescent power supply current test into the flip-flops, and inputting the test vectors in ascending order of the number of state transitions. Therefore, it is possible to reduce the time during which a large power supply current flows when each test vector is inputted, thereby reducing the quiescent stability waiting time, resulting in a reduction in the test time of the IDDQ test.

According to Claim 6 of the present invention, in the semiconductor testing method defined in Claim 3, the test for the semiconductor device is performed for each semiconductor device in a semiconductor integrated circuit. Therefore, the IDDQ test can be performed to each semiconductor device in the semiconductor integrated circuit, thereby reducing the analysis time for specifying faulty parts.

According to Claim 7 of the present invention, in the semiconductor testing method defined in Claim 4, the test for the semiconductor device is performed for each semiconductor device in a semiconductor integrated circuit. Therefore, the IDDQ test can be performed to each semiconductor device in the semiconductor integrated circuit, thereby reducing the analysis time for specifying faulty parts.

### BRIEF DESCRIPTION OF THE DRAWINGS

FIG. 1 is a diagram illustrating the construction of an FF in a semiconductor device to which a semiconductor testing method according to a first embodiment of the present invention is performed.

FIG. 2 is an operation waveform diagram for explaining the function of the FF in the semiconductor device according to the first embodiment of the present invention.

FIG. 3 is a diagram illustrating a semiconductor device according to the first embodiment of the present invention.

FIG. 4 is a schematic flowchart of an IDDQ test method as a semiconductor test method according to the first embodiment of the present invention.

FIG. 5 is a diagram illustrating a power supply current waveform which is obtained when performing the IDDQ test method as the semiconductor test method according to the first embodiment of the present invention.

FIG. 6 is a diagram illustrating a power supply current waveform of a combinational circuit which is obtained when performing an IDDQ test method as a semiconductor test method according to a second embodiment of the present invention.

FIG. 7 is a diagram illustrating a method for rearranging test vector inputs in an IDDQ test method as a semiconductor test method according to a third embodiment of the present invention.

FIG. 8 is a diagram illustrating the construction of a semiconductor device according to a fourth embodiment of the present invention.

FIG. 9 is a diagram illustrating the construction of a conventional semiconductor device having a scan test system.

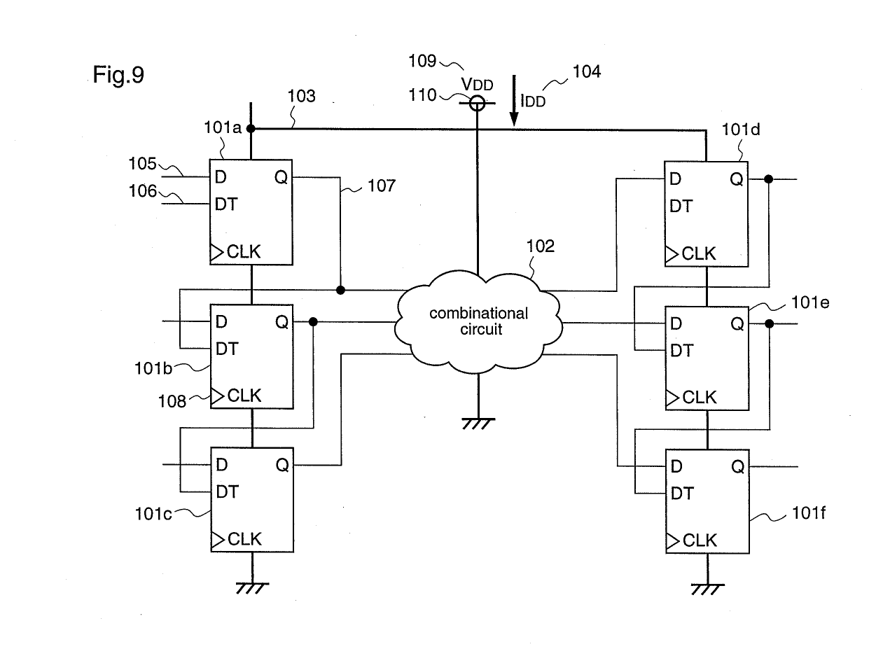

FIG. 10 is a schematic flowchart of an IDDQ test for the conventional semiconductor device having the scan test system.

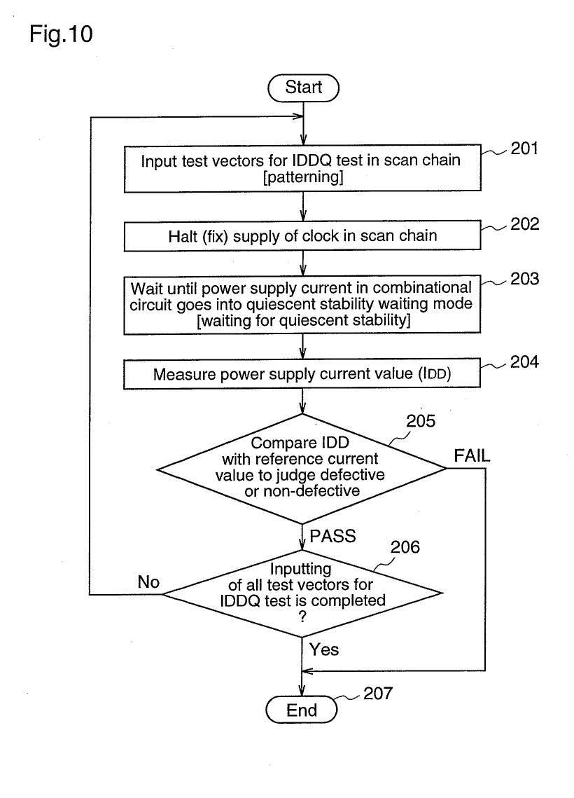

FIG. 11 is a diagram illustrating a power supply current waveform of the conventional IDDQ test.

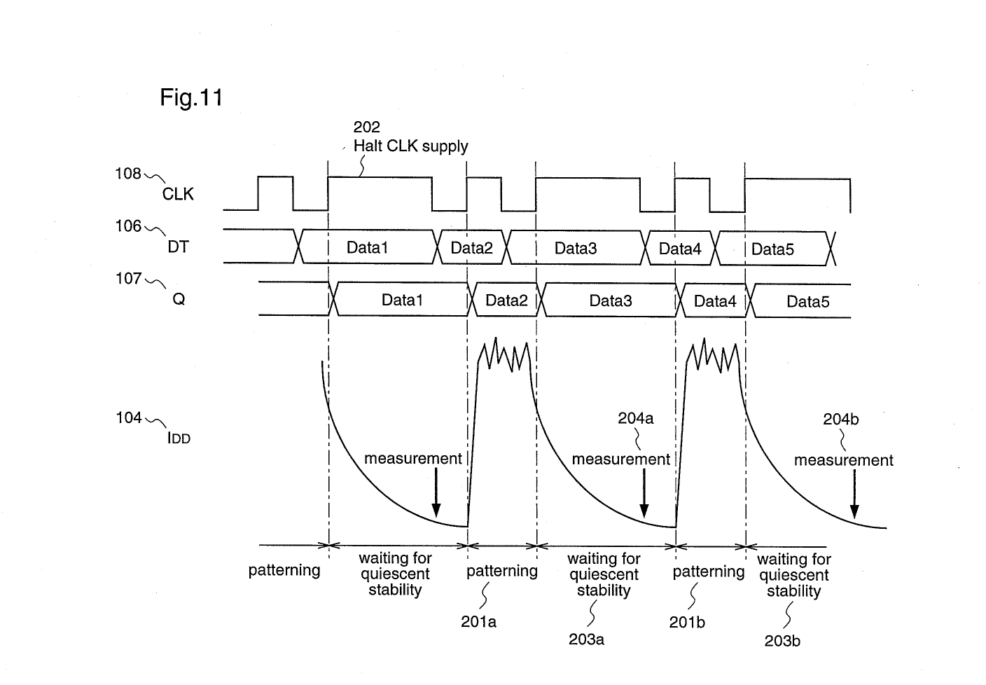

### DESCRIPTION OF REFERENCE NUMERALS

101a to 101f . . . first to sixth flip-flops
102 . . . combinational circuit
103 . . . power supply wiring
104 . . . power supply current value
105 . . . D terminal
106 . . . DT terminal
107 . . . Q terminal
108 . . . CLK terminal
109 . . . power supply voltage
110 . . . power supply
300 . . . flip-flop
301 . . . clock input terminal (CLK terminal)
302 . . . ordinary data input terminal (D terminal)
303 . . . scan chain data input terminal (DT terminal)
304 . . . load/hold terminal (IDDQ_LH terminal)
305 . . . data output terminal (Q terminal)
306 . . . scan chain data output terminal (QT terminal)
307 . . . combinational circuit
401 . . . power supply wiring of FF
402 . . . power supply current value of FF
403 . . . power supply wiring of combinational circuit
404 . . . power supply current value of combinational circuit
405 . . . power supply voltage of FF
406 . . . power supply voltage of combinational circuit
407 . . . power supply for FF
408 . . . power supply for combinational circuit
605 . . . inclination of power supply current value of non-defective product
606 . . . inclination of power supply current value of defective product
607 . . . switching current
801 . . . semiconductor device
802 to 805 . . . first to fourth functional blocks
806 . . . IDDQ_LH control circuit
807 . . . control terminal
808 . . . IDDQ_LH external input terminal
809 to 812 . . . first to fourth IDDQ_LH terminals

### BEST MODE TO EXECUTE THE INVENTION

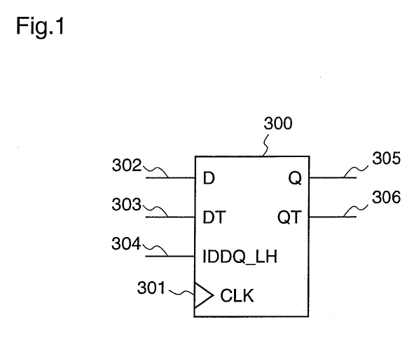

FIG. 1 is a diagram illustrating the configuration of a flip-flop included in a semiconductor device which executes an IDDQ test as a semiconductor testing method according to a first embodiment of the present invention.

In FIG. 1, a flip-flop (FF) 300 according to the first embodiment includes a clock input terminal (CLK terminal) 301, a normal data input terminal (D terminal) 302, a scan chain data input terminal (DT terminal) 303, an IDDQ_load/hold terminal (IDDQ_LH terminal) 304, a data output terminal (Q terminal) 305, and a scan chain data output terminal (QT terminal) 306.

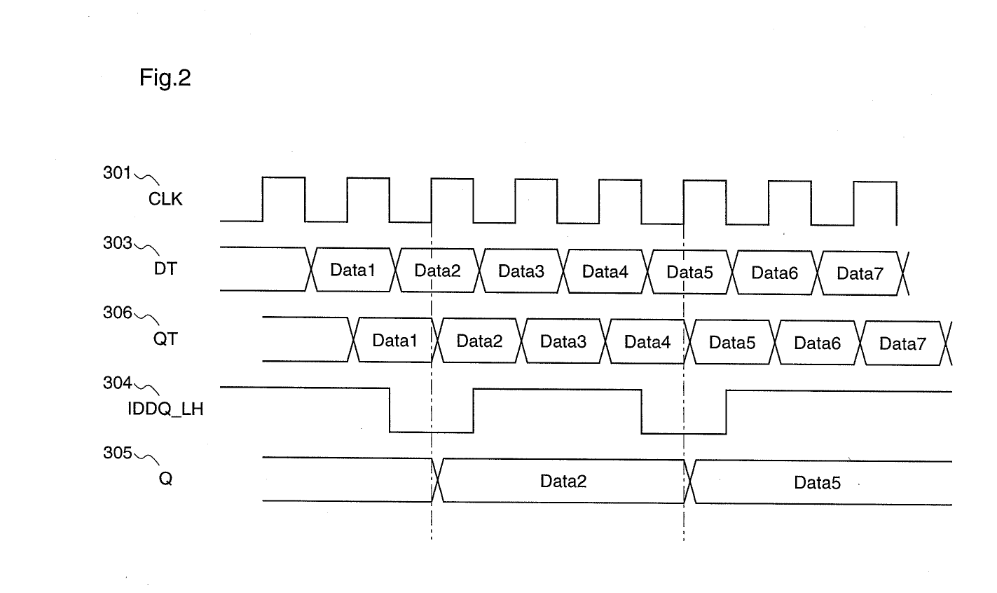

FIG. 2 is an operation waveform diagram for explaining the functions of the FF in the semiconductor device according to the first embodiment.

In FIG. 2, it is assumed that the data at the DT terminal 303 are latched at the rising edges of the clock supplied from the CLK terminal 301.

The scan chain data (test vectors for the IDDQ test) inputted from the DT terminal 303 are outputted from the QT terminal 306. On the other hand, when the test vectors for the IDDQ test are input to the combinational circuit, the test vectors are outputted from the Q terminal 305. At this time, the data output from the Q terminal 305 is controlled by the IDDQ_LH terminal 304. In this first embodiment, when the IDDQ_LH terminal 304 is at L input, the data at the DT terminal 303 are latched at the rising edges of the clock. When the IDDQ_LH terminal 304 is at H input, the data at the DT terminal 303 which are already latched are held irrespective of the clock. For example, as shown in FIG. 2, when the IDDQ_LH terminal 304 is H input, Data2 is held, and when the IDDQ_LH terminal 304 is L input, Data5 is newly output from the Q terminal 305.

As described above, in the FF shown in FIG. 1, the scan chain is constituted using the QT terminal 306 to output the test vectors for the IDDQ test, and simultaneously, the state where the test vectors for the IDDQ test are outputted to the combinational circuit can be maintained using the IDDQ_LH terminal 304 and the Q terminal 305.

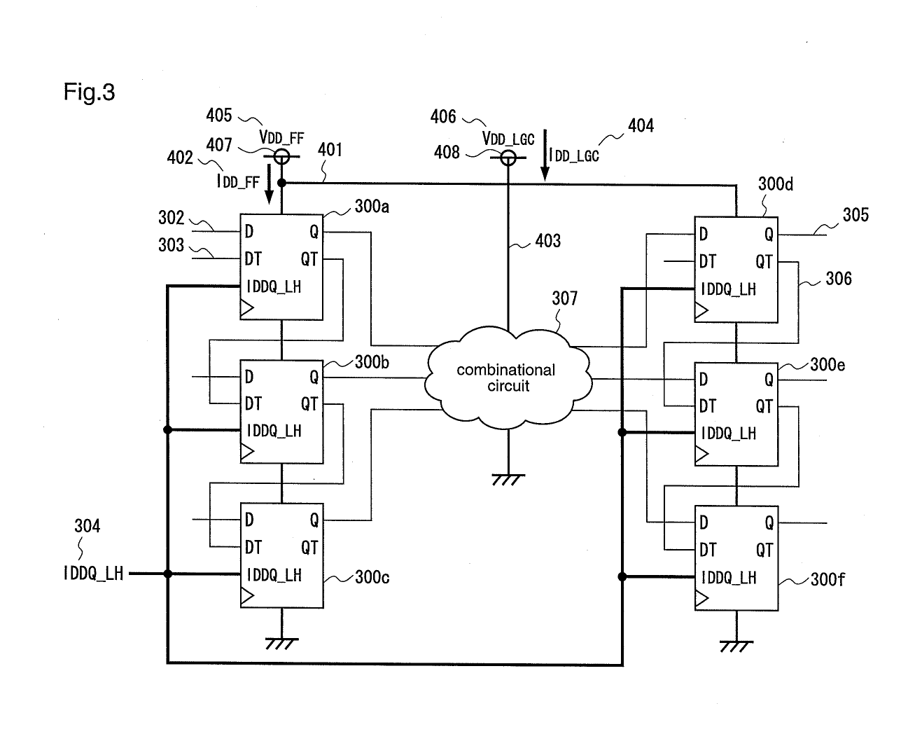

FIG. 3 is a diagram illustrating the construction of the semiconductor device according to the first embodiment of the present invention.

In FIG. 3, the semiconductor device according to the first embodiment includes first to sixth FFs 300a to 300f each having the construction shown in FIG. 1, and a combinational circuit 307. A power supply current (IDD_FF) 402 and a power supply voltage (VDD_FF) 405 are supplied from a flip-flop power supply 407 to the first to sixth FFs 300a to 300f which are connected to a power supply wiring 401, and a power supply current (IDD_LGC) 404 and a power supply voltage (VDD_LGC) 406 are supplied from a combinational circuit power supply 408 to the combinational circuit 307 connected to a power supply wiring 403.

Hereinafter, a description will be given of the operation when the IDDQ test method as the semiconductor testing method of the first embodiment is performed to the semiconductor device.

Initially, in the patterning of the scan chain, the power supply current 402 and the power supply voltage 405 are supplied from the power supply wiring 401 to the first to sixth FFs 300a to 300f. For example, the data inputted from the DT terminal 303 of the first FF 300a sets the first FF 300a in the shift register state and is output from the QT terminal 306, and the data for the scan chain is input to the second FF 101b in the scan chain.

The power supply current 404 and the power supply voltage 406 are supplied from the power supply wiring 403 to the combinational circuit 307, and when the patterning of the scan chain is completed, the test vector for the IDDQ test from the DT terminal 303 is output from the Q terminal 305 to the combinational circuit 307 with the IDDQ_LH terminal 304 being at L input (load state). Further, until the patterning of the scan chain is completed, the output from the Q terminal 305 to the combinational circuit 307 is fixed with the IDDQ_LH terminal 304 being H input (hold state).

As described above, in the first embodiment, the scan chain is realized by using the QT terminals 306 of the first to third FFs 300a to 300c and the fourth to sixth FFs 300d to 300f, and the test vectors for the IDDQ test are input to the combinational circuit 307 by using the Q terminals 305 of the first to third FFs 300a to 300c. At this time, the power supply current value 402 that flows in the first to sixth FFs 300a to 300f and the power supply current value 404 that flows in the combinational circuit 307 can be monitored, respectively. When the IDDQ test for the combinational circuit 307 is carried out, the power supply current value (IDDQ value) 402 in the quiescent state which flows in the first to sixth FFs 300a to 300f is not measured.

Further, when inputting the test vectors for the IDDQ test, the outputs of the Q terminals 305 can be held in the first to third FFs 300a to 300c simultaneously with setting of the next test vectors on the scan chain using the QT terminals 306, and thereby the quiescent stability waiting and the patterning of the next test vectors can be simultaneously performed.

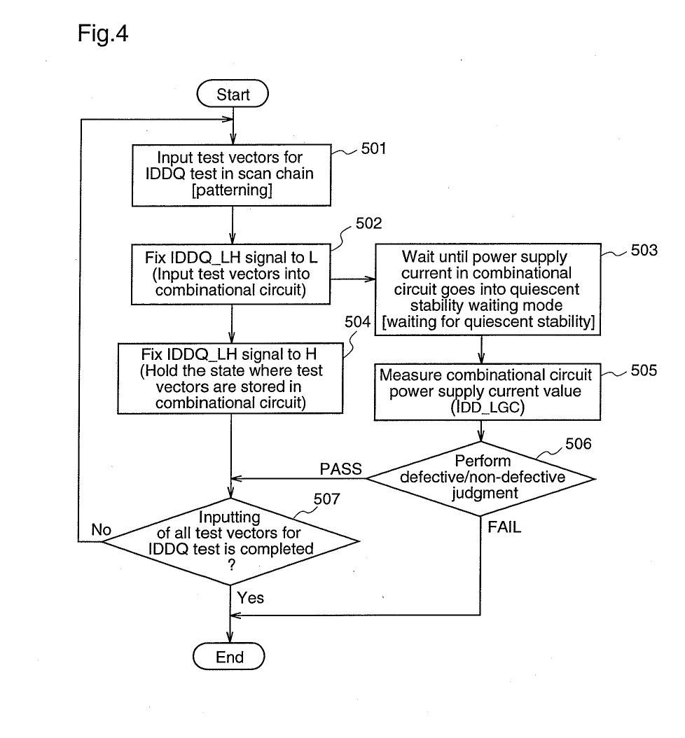

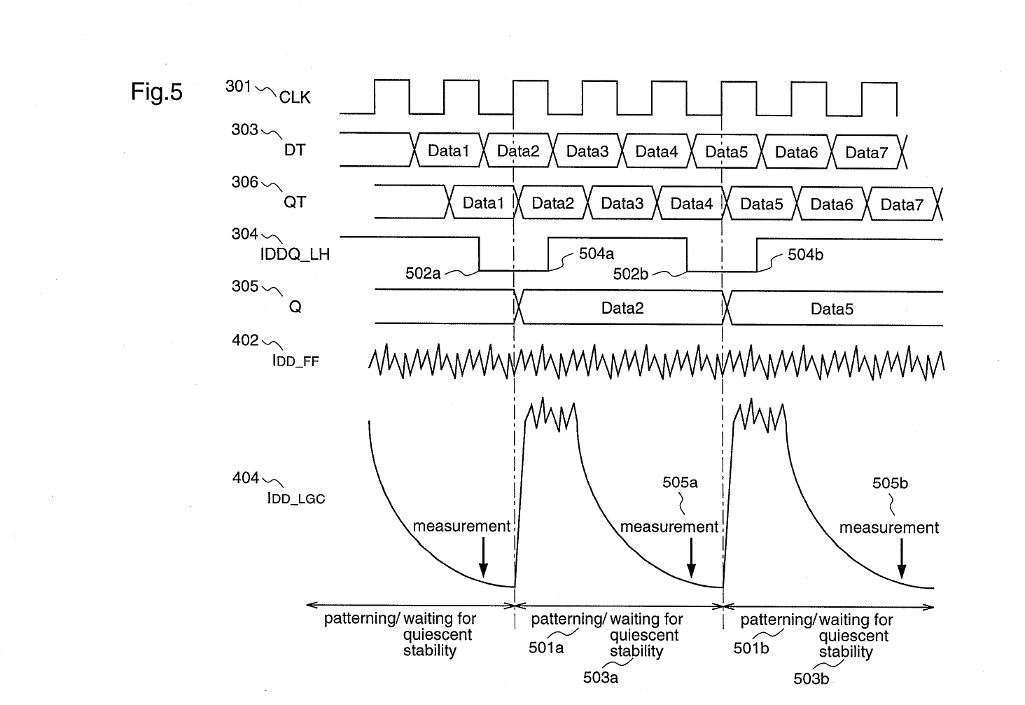

Next, the IDDQ test method as the semiconductor testing method according to the first embodiment will be described with reference to FIGS. 4 and 5.

FIG. 4 is a schematic flowchart of the IDDQ test method according to the first embodiment.

In FIG. 4, IDDQ test vectors are input to the scan chain and patterned in step 501. The patterning is performed with the IDDQ_LH signal being fixed at H. Next, when the test vectors are set in the scan chain, the IDDQ_LH terminal 304 is set to L input in step 502, and thereby data inputted from the DT terminals 303 of the first to third FFs 300a to 300c are latched in step 502. Then, the test vectors are input to the combinational circuit 307 from the Q terminals 305 of the first to third FFs 300a to 300c. Next, in step 504, the IDDQ_LH signal is fixed at H to fix the outputs from the Q terminals 305 to the combinational circuit 307, thereby holding the state where the test vectors are input to the combinational circuit 307. Simultaneously with the fixing of the IDDQ_LH signal at H to hold the state where the test vectors are input to the combinational circuit 307 (step 504), it is waited until the power supply current 404 in the combinational circuit 307 goes into the quiescent stability mode (step 503). When the power supply current 404 goes into the quiescent stability mode in step 503, the power supply current 404 in the combinational circuit 307 is measured in step 505. When the IDDQ test for the combinational circuit 307 fails (FAIL in step 506), the IDDQ test is ended. When the IDDQ test for the combinational circuit 307 passes (PASS in step 506), it is checked whether inputting of all the test vectors for the IDDQ test has been completed or not (step 507).

When inputting of all the test vectors for the IDDQ test is not yet completed (No in step 507), the process returns to step 501. When inputting of all the test vectors for the IDDQ test has been completed (Yes in step 507), the IDDQ test is ended.

In this first embodiment, before starting the IDDQ test for the semiconductor device, the shift registers constituting the scan chain may be previously tested, and the FFs are tested by performing either or both of a monitor test as to whether input and output to/from the FFs in the scan chain are normally performed or not and an IDDQ test for the FFs after the signal values are set in all the registers in the scan chain. Since the semiconductor device is a defective product if the test for the FFs fails, it becomes unnecessary to perform the IDDQ test of the first embodiment to the defective semiconductor device.

FIG. 5 is a diagram illustrating the power supply current waveforms obtained when performing the IDDQ test method as the semiconductor testing method of the first embodiment.

As shown in FIG. 5, the input of the IDDQ_LH terminal 304 is fixed at L for one clock period (step 502a,502b), whereby the data are latched in the FF 300, and the test vectors for the IDDQ test are output from the Q terminal to the combinational circuit 307. Then, the input to the IDDQ_LH terminal 304 is fixed at H, whereby the output from the Q terminal 305 to the combinational circuit 307 can be fixed. In the conventional IDDQ test method, the quiescent stability waiting is performed after the patterning and the patterning of the next test vectors is started after the power supply current value is measured. In this first embodiment, however, the quiescent stability waiting and the patterning of the next test vectors can be simultaneously performed, thereby reducing the entire test time of the IDDQ test.

More specifically, in the semiconductor device of the first embodiment, even while waiting for quiescent stability of the combinational circuit 307 which is operated by the outputs from the Q terminals 305 of the first to third FFs 300a to 300c, the patterning of the next test vectors, i.e., the operation of latching the data inputted to the DT terminals 303 at the rising edge of the clock 301 and outputting the data from the QT terminals 306, is carried out.

For example, when the input to the IDDQ_LH terminal 304 is fixed to L for one clock period (step 502a), the test vector (data 2) inputted from the DT terminal 303 to the first FF 300a is latched by the first FF 300a at the rising edge of the clock 301. When the input to the IDDQ_LH terminal 304 is H (step 504a), patterning of the data 2 is carried out (step 501a), and the data 2 is output from the Q terminal 305 to the combinational circuit 307. Subsequently, the data 3, 4, 5, . . . are input to the first FF 300a through the DT terminal.

Next, when the patterning of the data 2 (step 501a) is completed and the input to the IDDQ_LH terminal 304 is fixed to L for one clock period (step 502b), the data 5 is latched in the first FF 300a while quiescent stability waiting for the data 2 is performed in the combinational circuit 307 (step 503b). When the input to the IDDQ_LH terminal 304 is H (step 504b), patterning of the data 5 is performed (step 501b), and the data 5 is output from the Q terminal 305 to the combinational circuit 307.

Simultaneously with the quiescent stability waiting for the data 2 (step 503b), patterning of the data 5 is performed (step 501b). When the data 2 goes into the quiescent stability mode, measurement is performed (step 505b).

As described above, according to the first embodiment, the values of the test vectors for the quiescent power supply current test are held in the flip-flops 300 on the basis of the load/hold signal until inputting of the test vectors into all the flip-flops in the scan chain is completed, and when inputting of the next test vectors into all the flip-flops 300 is completed, the values of the test vectors in the flip-flops 300 are rewritten to the values of the next test vectors, and after the values of the test vectors in the flip-flops 300 in the scan chain have been rewritten, the values of the rewritten test vectors in the flip-flops 300 are held. Therefore, the quiescent stability waiting and the patterning of the next test vectors can be simultaneously performed, thereby reducing the test time of the IDDQ test.

### Embodiment 2

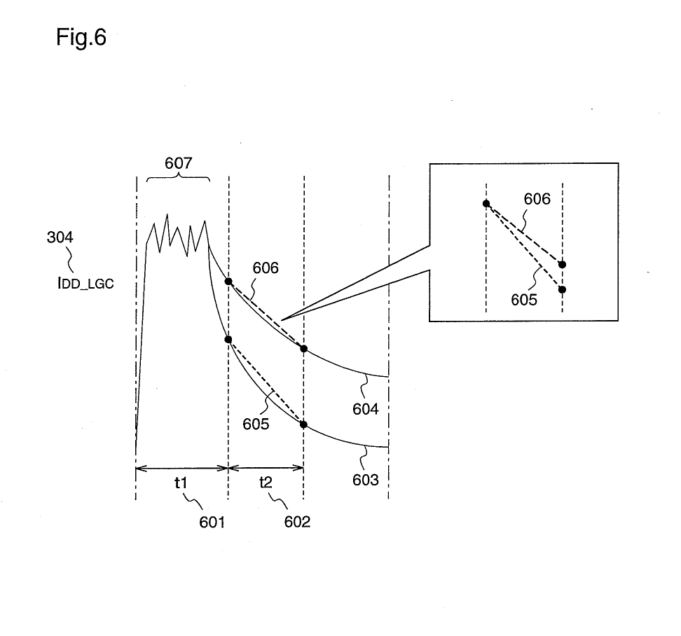

Hereinafter, an IDDQ test method for a semiconductor device as a semiconductor testing method according to a second embodiment of the present invention will be described with reference to FIG. 6.

FIG. 6 is a diagram illustrating a power supply current waveform from the combinational circuit obtained when performing the IDDQ test method as the semiconductor testing method of the second embodiment. Since the construction of the semiconductor device is identical to that shown in FIG. 3, repeated description is not necessary.

With reference to FIG. 6, at a timing after a predetermined period t1(601) has passed from when the test vector was input to the combinational circuit 307, and at a timing after a predetermined period t2(602) has passed from t1, the IDDQ values after the lapse of t1(601) and the IDDQ values after the lapse of t2(602) of the power supply current waveform 603 for a non-defective product and the power supply current waveform 604 for a defective product are measured, respectively, and an inclination 605 between these two points of the IDDQ value after the lapse of t1(601) and the IDDQ value after the lapse of t2(602) of the non-defective product and an inclination 606 between the two points of the IDDQ value after the lapse of t1(601) and the IDDQ value after the lapse of t2(602) of the defective product are calculated. Here, t1(601) corresponds to a period from when the test vector is input to the conventional circuit 307 to when the flowing of the switching current 607 in the combinational current 307 is completed. Further, it is assumed that the IDDQ value in this second embodiment is the power supply current value in the quiescent state which flows in the combinational circuit 307.

While in this second embodiment an inclination between the two points of the IDDQ value at t1(601) and the IDDQ value at t2(602) is calculated, the IDDQ values at more than two points may be measured to approximately calculate an inclination from those IDDQ values. The number of the IDDQ values to be measured is not restricted.

When performing the IDDQ test as the semiconductor testing method of the second embodiment, initially, the inclination between the two points of the IDDQ values of the non-defective product and the inclination 606 between the two points of the IDDQ values of the defective product are calculated. As shown in FIG. 6, since the power supply current 604 of the defective product is larger than the power supply current 603 of the non-defective product and thereby the IDDQ value of the defective product becomes larger than the IDDQ value of the non-defective product, the inclination 605 of the non-defective product becomes larger than the inclination 606 of the non-defective product.

Therefore, when performing the IDDQ test as the semiconductor testing method, the power supply current values are measured and an inclination between two power supply current values is obtained during the quiescent stability waiting mode after the patterning, and the semiconductor device is judged as a defective product when the inclination is gentler than the inclination 605 of the non-defective product while it is judged as a non-defective product when the inclination is larger than the inclination 605 of the non-defective product.

As described above, according to the second embodiment, the power supply current values at two or more points are measured at a timing after a predetermined period has passed from when the test vectors were input to the combinational circuit and at a timing after a further predetermined period from that timing, and an inclination between these points is calculated, and then the calculated inclination is compared with a reference inclination, until the values of the test vectors in the flip-flops 300 are rewritten when inputting of the next test vectors into all the flip-flops 300 is completed while the values of the test vectors which have been held in the flip-flops 300 before being rewritten to the next test vectors are input to the combinational circuit 307, and thereby the quiescent power supply current at the external terminal for supplying a power supply voltage to the combinational circuit goes into the quiescent stability mode. Therefore, the defective/non-defective judgment can be performed before measuring the IDDQ values after the combinational circuit 307 is waited for quiescent stability and goes into the quiescent stability mode, thereby reducing the test time of the IDDQ test.

### Embodiment 3

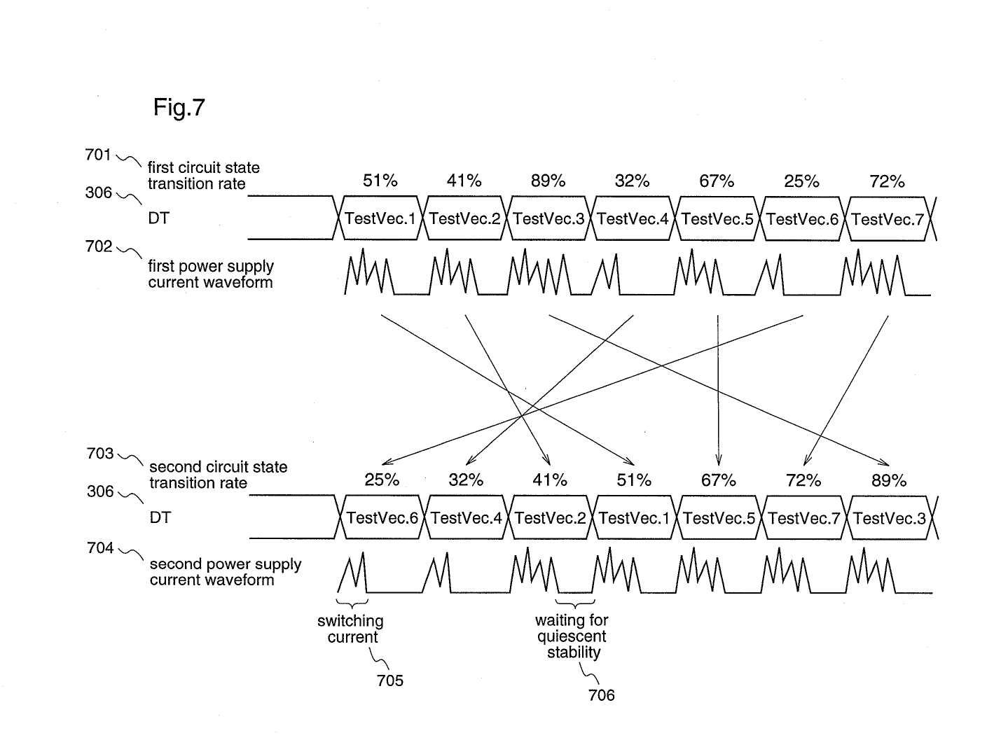

An IDDQ test method as a semiconductor testing method according to a third embodiment of the present invention will be described with reference to FIG. 7. In this third embodiment, before the test vectors for the IDDQ test are input to the FFs, the number of state transitions in the combinational circuit 307 is calculated for each test vector, and inputting of the test vectors is performed in ascending order of the number of state transitions.

FIG. 7 is a diagram for explaining the method of rearranging the inputs of the test vectors in the IDDQ test method as the semiconductor testing method according to the third embodiment. Since the construction of the semiconductor device is identical to that shown in FIG. 3, repeated description is not necessary.

FIG. 7 shows the first and second circuit state transition rates 701 and 703 of the test vectors and the first and second power supply current waveforms 702 and 704, which are obtained when the test vectors for the IDDQ test are input from the DT terminal 306 of the FF 101. The circuit state transition rate is the probability that the state of the combinational circuit might transit when the test vector is input to the combinational circuit.

Initially, the first circuit state transition rate 701 of the combinational circuit 307 to be obtained when the test vector is input thereto is previously calculated using a simulation or the like. When the test vector is input to the combinational circuit 307, a switching operation due to the test vector input occurs in the combinational circuit 307. At this time, a large power supply current called a switching current 705 flows in the combinational circuit 307. As the first circuit state transition rate 701 of the combinational circuit 307 is larger, the period during which the switching current 705 flows becomes longer. On the other hand, when the period during which the switching current 705 flows is short, the combinational circuit can immediately go into the quiescent stability waiting mode, and thereby the test time of the IDDQ test can be reduced.

In the semiconductor testing method according to the third embodiment, before the test vectors are input to the FFs, the number of state transitions in the combinational circuit 307 is calculated for each of the test vectors. The first circuit state transition rates 701 in the initial inputting order of the test vectors are 51%, 41%, 89%, 32%, 67%, 25%, 72% for the test vectors 1, 2, 3, 4, 5, 6, 7 in the inputting order of the test vectors, respectively. On the other hand, the second circuit state transition rates 702 which are obtained when the test vectors are rearranged in the ascending order of the number of state transitions, i.e., 6, 4, 2, 1, 5, 7, 3, are 25%, 32%, 41%, 51%, 67%, 72%, 89% in the inputting order of the test vectors, respectively. Therefore, the period during which the switching current 705 flows in the combinational circuit 307 can be reduced by rearranging the inputting order of the test vectors so that the state transition rates are arranged in the ascending order, and thereby the combinational circuit 307 can go into the quiescent stability waiting mode immediately after the inputting of the test vectors. Accordingly, the entire test time of the IDDQ test can be reduced by judging the semiconductor device as a defective product in the test using the test vectors having relatively small numbers of state transitions which are inputted in the beginning stage, and terminating the IDDQ test before the test vectors having the relatively large numbers of state transitions are inputted.

As described above, according to the third embodiment of the present invention, before the test vectors for the quiescent power supply current test are input to the FFs, the number of state transitions in the combinational circuit is calculated for each of the test vectors for the quiescent power supply current test, and the test vectors are inputted in the ascending order of the numbers of state transitions. Therefore, the entire test time of the IDDQ test can be reduced by judging the semiconductor device as a defective product in the test using the test vectors having relatively small numbers of state transitions which are inputted in the beginning stage, and terminating the IDDQ test before the test vectors having the relatively large numbers of state transitions are inputted.

### Embodiment 4

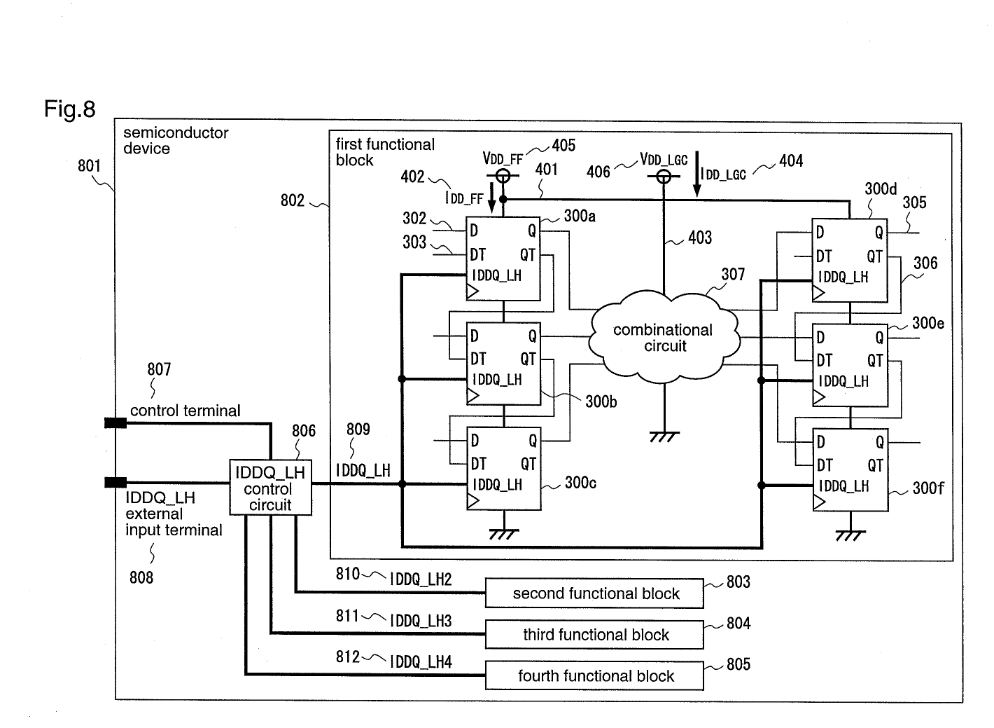

An IDDQ test method as a semiconductor testing method according to a fourth embodiment of the present invention will be described with reference to FIG. 8.

FIG. 8 is a diagram illustrating the construction of a semiconductor device according to the fourth embodiment of the present invention. The semiconductor device according to the fourth embodiment includes plural semiconductor units.

In FIG. 8, the semiconductor device 801 has, in its inside, a first functional block 802, a second functional block 803, a third functional block 804, and a fourth functional block 804. Since the constructions of the respective functional blocks 802 to 805 are identical to that of the semiconductor device shown in FIG. 3, repeated description is not necessary.

The semiconductor device 801 according to the fourth embodiment includes an IDDQ_LH control circuit 806 for controlling the states of IDDQ_LH terminals 809 to 812 of the respective functional blocks 802 to 805. A control terminal 807 for controlling the inputs to the IDDQ_LH terminals 809 to 812 of the respective functional blocks 802 to 805 and an IDDQ_LH external input terminal 808 for inputting an IDDQ_LH signal are connected to the IDDQ_LH control circuit 806.

The IDDQ_LH control circuit 806 performs control so that the IDDQ_LH signal from the IDDQ_LH external input terminal 808 is input to only a specific functional block among the first to fourth functional blocks 802 to 805, on the basis of a load/hold control signal from the control terminal 807.

Since the conventional semiconductor device having plural functional blocks does not have the IDDQ_LH control circuit 806 shown in FIG. 8 and the IDDQ_LH signal is simultaneously input to all the plural functional blocks in the semiconductor device, there are cases where it is unclear which functional block's operation result the output from the semiconductor device is. In the semiconductor device according to the fourth embodiment, however, either an L input or an H input can be inputted as an input to the IDDQ_LH terminal for each functional block, and thereby the IDDQ test can be performed for each functional block. As for this IDDQ test, the IDDQ test described in any of the first to third embodiments may be used.

While in this fourth embodiment four functional blocks, i.e., the first to fourth functional blocks 802 to 805, are adopted, the number of the functional blocks is not particularly restricted. Further, the number of the control terminals 807 for controlling the inputs to the IDDQ_LH terminals 809 to 812 of the respective functional blocks 802 to 805 may be one or more, and it is not particularly restricted.

As described above, according to the fourth embodiment, since the load/hold control circuit 806 for controlling the input of the load/hold signal to the respective functional blocks on the basis of the load/hold control signal inputted from the control terminal 807 is provided in the semiconductor integrated circuit 801 having the first to fourth functional blocks 802 to 805. Therefore, the IDDQ test can be performed to each of the respective functional blocks in the semiconductor integrated circuit, and thereby the analysis can be performed in functional block units, resulting in a reduction in the time to be spent on the analysis for specifying faulty parts.

### APPLICABILITY

The present invention is useful as a system LSI on which a scanning test system is mounted.

1. A semiconductor device having plural flip-flops to which test vectors for a quiescent power supply current test are inputted during a scan test mode, and ordinary data are inputted during an ordinary use mode, said semiconductor device comprising:
a combinational circuit to which the test vectors or the ordinary data are supplied from the plural flip-flops in a scan chain;
a flip-flop power supply for supplying a power supply voltage to the flip-flops, which is connected to the flip-flops by a power supply voltage supply wiring;
a combinational circuit power supply for supplying a power supply voltage to the combinational circuit, which is connected to the combinational circuit by a power supply voltage supply wiring; and
each of the flip-flops including
a load/hold terminal to which a load/hold signal is inputted, said load/hold signal controlling as to whether the test vectors supplied from the scan chain during the quiescent power supply current test mode should be held in the flip-flop as data to be outputted to the combinational circuit, or outputted to the combinational circuit,
an ordinary data output terminal for outputting the ordinary data from the flip-flops to the combinational circuit, and
a scan chain data output terminal for outputting the test vectors from an n-th stage flip-flop (n: integer) to an (n+1)th stage flip-flop in the scan chain.

2. A semiconductor device having a plurality of semiconductor devices as defined in claim 1 wherein
a load/hold control circuit for controlling inputs of load/hold signals to the respective semiconductor devices on the basis of a load/hold control signal supplied from a control terminal is provided in the semiconductor device including the plural semiconductor devices.

3. A method for testing a semiconductor device having plural flip-flops, and a combinational circuit which receives the outputs of the plural flip-flops, said method comprising the steps of:
holding values of test vectors for a quiescent power supply current test in the flip-flops until inputting of the test vectors to all the flip-flops in a scan chain is completed;
rewriting the values of the test vectors in the flip-flops to values of next test vectors when inputting of the next test vectors to all the flip-flops is completed, and holding the values of the rewritten test vectors in the flip-flops after the values of the test vectors in the flip-flops have been rewritten; and
measuring a quiescent power supply current value at an external power supply terminal for the combinational circuit, and comparing the measured current value with a reference current value, when the values of the test vectors in the flip-flops are rewritten to the values of the next test vectors, and the values of the test vectors that have been held in the flip-flops before being rewritten to the next test vectors are input to the combinational circuit, and thereby the quiescent power supply current of the combinational circuit goes into the quiescent mode.

4. A method for testing a semiconductor device having plural flip-flops and a combinational circuit which receives the outputs from the plural flip-flops, said method comprising the steps of:
holding values of test vectors for a quiescent power supply current test in the flip-flops until inputting of the test vectors to all the flip-flops in a scan chain is completed;
rewriting the values of the test vectors in the flip-flops to values of next test vectors when inputting of the next test vectors to all the flip-flops is completed, and holding the values of the rewritten test vectors in the flip-flops after the values of the test vectors in the flip-flops have been rewritten; and
measuring the power supply current values at two or more points at a timing after a predetermined period has passed from when the test vectors are input to the combinational circuit and a timing after a further predetermined period has passed from that timing to calculate an inclination between the two current values, and comparing this inclination with a reference inclination, until the values of the test vectors in the flip-flops are rewritten to the values of the next test vectors, and the values of the test vectors that have been held in the flip-flops before being rewritten to the next test vectors are input to the combinational circuit and thereby the quiescent power supply current of the combinational circuit goes into the quiescent mode.

5. A semiconductor testing method as defined in claim 3 further including
previously calculating the number of state transitions which occur when each test vector for the quiescent power supply current test is input to the combinational circuit, before inputting the test vectors for the quiescent power supply current test into the flip-flops, and inputting the test vectors in ascending order of the number of state transitions.

6. A semiconductor test method as defined in claim 3 wherein
the test for the semiconductor device is performed for each semiconductor device in a semiconductor integrated circuit.

7. A semiconductor test method as defined in claim 4 wherein
the test for the semiconductor device is performed for each semiconductor device in a semiconductor integrated circuit.

8. A semiconductor testing method as defined in claim 4 further including
previously calculating the number of state transitions which occur when each test vector for the quiescent power supply current test is input to the combinational circuit, before inputting the test vectors for the quiescent power supply current test into the flip-flops, and inputting the test vectors in ascending order of the number of state transitions.
